(19) United States
(12) Patent Application Publication
(10) Pub. No.: US 2022/0283738 A1
(43) Pub. Date: Sep. 8, 2022

(54) FLASH MEMORY AND WRITING METHOD THEREOF

(71) Applicant: MACRONIX International Co., Ltd., Hsinchu (TW)

(72) Inventors: Chun-Lien Su, Taichung City (TW); Chang-Ting Chen, Hsinchu City (TW)

(73) Assignee: MACRONIX International Co., Ltd., Hsinchu (TW)

(21) Appl. No.: 17/192,807

(22) Filed: Mar. 4, 2021

(51) Int. Cl. G06F 3/06; G06F 12/06; G11C 16/04; G11C 16/10; G11C 16/14

(52) U.S. Cl. CPC G06F 3/0659; G06F 3/0604; G06F 3/0652; G06F 3/0679; G06F 3/064; G06F 12/0607; G11C 16/0483; G11C 16/10; G11C 16/14; G06F 2212/1024; G06F 2212/1028; G06F 3/0625; G11C 16/24

(57) ABSTRACT

A flash memory and a writing method thereof are provided. The flash memory includes a plurality of memory blocks and a plurality of multiplex circuits. The memory blocks are arranged into a plurality of memory banks. Each of the memory blocks transmits a plurality of erase voltages or a plurality of program voltages to the corresponding memory bank for executing an erase operation or a program operation. The program operation is executed by one of the memory banks while the erase operation is executed by another one of the memory banks according to a programming while erasing instruction.

### TECHNICAL FIELD

The invention relates to a flash memory and a writing method thereof, and more particularly, to a flash memory and a writing method thereof that can execute a programming while erasing operation.

### BACKGROUND

In NOR flash memories, the speed of performing an erase operation is much slower than the speed of performing a program operation. In the application of the Internet of Things, the so-called on-the-air firmware update is a very important function for the flash memory. Therefore, if the time required for data update by the flash memory can be effectively reduced, the risk due to power loss or defective software versions can be effectively reduced for the content of the flash memory.

### SUMMARY

The invention provides to a flash memory and a writing method thereof, which can accelerate a data writing speed of the memory by executing a programming while erasing operation and can reduce power consumption.

The flash memory of the invention includes a plurality of memory blocks and a plurality of multiplex circuits. The memory blocks are arranged into a plurality of memory banks. The multiplex circuits are coupled to the memory banks, respectively. Each of the memory blocks transmits a plurality of erase voltages or a plurality of program voltages to the corresponding memory bank for executing an erase operation or a program operation. The program operation is executed by one of the memory banks while the erase operation is executed by another one of the memory banks according to a programming while erasing instruction.

The writing method of the flash memory of the invention includes: arranging a plurality of memory blocks into a plurality of memory banks; providing a plurality of multiplex circuits to respectively correspond to the memory banks so that each of the memory blocks transmits a plurality of erase voltages or a plurality of program voltages to the corresponding memory bank for executing an erase operation or a program operation; and executing the program operation by one of the memory banks while executing the erase operation by another one of the memory banks according to a programming while erasing instruction.

Based on the above, the memory blocks are arranged into multiple memory banks in the invention. The multiplex circuits are used to provide different voltage supply pipelines. According to the programming while erasing instruction, multiple erase voltages are provided to one of the memory banks for executing the erase operation, and multiple program voltages are provided to another one of the memory banks for executing the program operation. In the embodiment of the invention, among the different memory banks, the program operation and erase operation can be executed synchronously to effectively reduce the time required for memory writing.

### BRIEF DESCRIPTION OF THE DRAWINGS

FIG. 1A is a schematic diagram illustrating a flash memory in an embodiment of the invention.

FIG. 1B illustrates a block diagram of a flash memory chip according to an embodiment of present invention.

FIG. 2A to FIG. 2C are schematic diagrams illustrating an arranging method of memory blocks in an embodiment of the invention.

FIG. 3 is a schematic diagram illustrating a flash memory in another embodiment of the invention.

FIG. 4A and FIG. 4B are schematic diagrams illustrating various implementations of a multiplex circuit in the flash memory in the embodiments of the invention.

FIG. 5 is a schematic diagram of an implementation of multiple multiplex circuits corresponding to different memory banks in a flash memory according to an embodiment of the invention.

FIG. 6 illustrates a flowchart of operations of a programming while erasing operation executed by the flash memory in an embodiment of the invention.

FIG. 7 is a flowchart illustrating a writing method of a flash memory in an embodiment of the invention.

FIG. 8 is a flow chart of illustrating a writing method of a flash memory in another embodiment of the invention.

FIG. 9 illustrates a block diagram of a flash memory with a host chip according to an embodiment of present disclosure.

### DESCRIPTION OF THE EMBODIMENTS

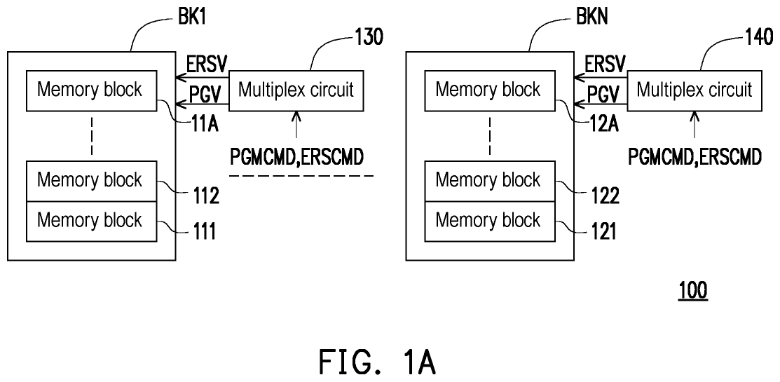

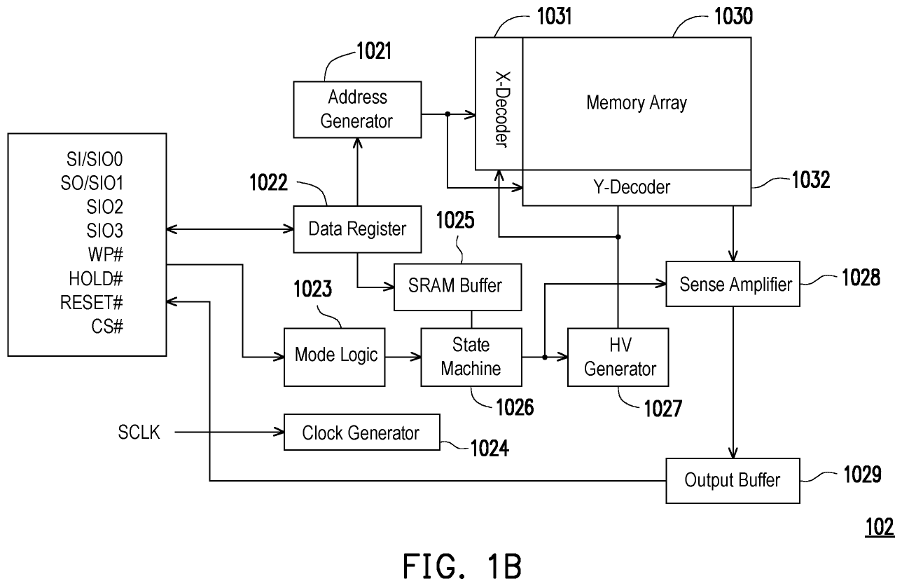

Referring to FIG. 1A, FIG. 1A is a schematic diagram illustrating a flash memory in an embodiment of the invention. A flash memory 100 includes a plurality of memory blocks 111 to 11A and 121 to 12A and a plurality of multiplex circuits 130 and 140. The memory blocks 111 to 11A are arranged into a memory bank BK1, and the memory blocks 121 to 12A are arranged into a memory bank BK2. The multiplex circuits 130 and 140 are coupled to the memory banks BK1 and BKN, respectively. Each of the multiplex circuits 130 and 140 transmits a plurality of erase voltages ERSV or a plurality of program voltages PGV to the corresponding memory banks BK1 and BKN for executing an erase operation or a program operation.

In this embodiment, the multiplex circuits 130 and 140 can conduct proper operation voltages according to a program instruction PGMCMD, or an erase instruction ERSCMD. One of the multiplex circuits 130 and 140 can make the corresponding memory bank (one of the memory banks BK1 and BKN) execute the erase operation according to the erase instruction ERSCMD. The other one of the multiplex circuits 130 and 140 can make the corresponding memory bank (the other one of the memory banks BK1 and BKN) execute the program operation according to the program instruction PGMCMD.

For instance, please refer to FIG. 1A and FIG. 1B, wherein FIG. 1B illustrates a block diagram of a flash memory chip according to an embodiment of present invention. The Flash memory chip 102 includes an address generator 1021, a data register 1022, a mode logic 1023, a clock generator 1024, a SRAM buffer 1025, a state machine 1026, a high voltage (HV) generator 1027, a sense amplifier 1028, an output buffer 1029, a memory array 1030, a X-decoder 1031 and a Y-decoder 1032. The output buffer 1029 outputs signal SO, or SIO0-SIO3 through an I/O interface 1033. The data register 1022 and mode logic 1023 may receive signals SI, SIO0-SIO3, WP #, HOLD #, RESET # and CS # through the I/O interface 1033. In here, the multiplex circuits 130 and 140 in FIG. 1A may be part of the HV generator 1027, the X decoder 1031 and the Y decoder 1032. The mode logic 1023 will determine commands received through the I/O interface 1033 and then feed into state machine 1026 to generate instructions to operate the flash memory chip 102 accordingly.

When the flash memory chip 102 receives the erase instruction ERSCMD, the multiplex circuit 130 can provide the erase voltages ERSV to the memory bank BK1 so that the memory bank BK1 can execute the erase operation. Meanwhile, the multiplex circuit 140 can provide the program voltages PGV to the memory bank BKN so that the memory bank BKN can execute the program operation if a program instruction PGMCMD is received with an address other than the memory bank BK1 to be erased, and here for example the address is located in the memory bank BKN. Here, it should be noted that in this example, a plurality of status flags can be set for the corresponding memory banks BK1 and BKN respectively. Take the memory block BK1 as an example, one status flag can record an erase status and another status flag can record a program status of the memory bank BK1. The multiplex circuits 130 and 140 can make the corresponding memory banks BK1 and BKN execute the erase operation or the program operation according to values of the status flags.

It is particularly worth noting that in the embodiment of the invention, the program operation of the memory bank BKN is executed synchronously with the erase operation of the memory bank BK1 in the above example. Under the premise that the erase operation requires a relatively long operation time, the program operation of the memory bank BKN does not require additional operation time. Therefore, the program operation of the memory bank BKN does not need to be completed in a hurry, but can be executed through a degraded program operation. Here, the so-called degraded program operation is achieved by reducing the number of bits of programmed memory cells and/or reducing (compared to a general program operation) voltage values the program voltages that produce a hot carrier injection effect. Accordingly, power consumption can be reduced by reducing a program current required in the program operation, and making the program current less than an expected value (the expected value can be equal to a current value of the program current required for the general program operation).

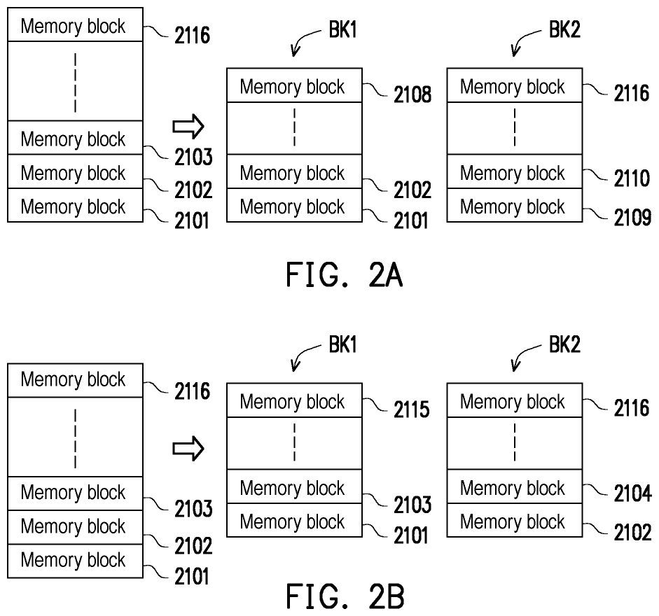

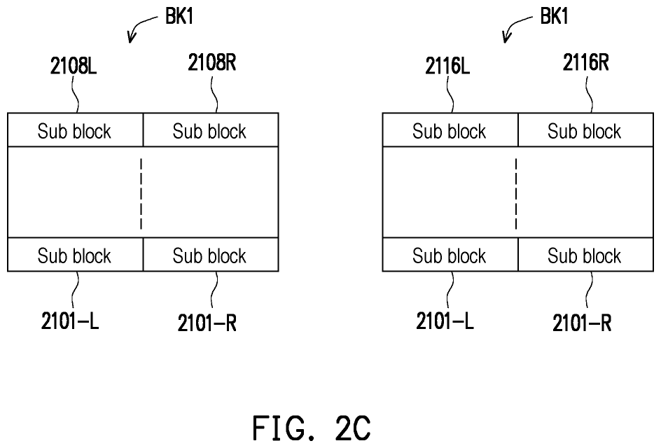

For an arranging method of memory blocks in the embodiment of the invention, reference can be made according to FIG. 2A to FIG. 2C, which are schematic diagrams illustrating the arranging method of memory blocks. In FIG. 2A, the flash memory includes memory blocks 2101 to 2116 with continuous physical addresses. The memory blocks 2101 to 2116 can be arranged into the memory banks BK1 and BK2. In the embodiment shown in FIG. 2A, the memory bank BK1 may include memory blocks 2101 to 2108 with the continuous physical addresses, and the memory bank BK2 may include memory blocks 2109 to 2116 with the continuous physical addresses.

In FIG. 2B, among the memory blocks included in the memory bank BK1 and the memory bank BK2, the physical addresses may be interleaved with each other. For example, according to an arrangement sequence of the physical addresses of the memory blocks 2101 to 2106, the memory bank BK1 may include the odd-numbered memory blocks 2101, 2103 . . . , 2115; the memory bank BK2 may include the even-numbered memory blocks 2102, 2104 . . . , 2116. The memory bank BK1 and the memory bank BK2 can be arranged by an interleaved arrangement, and the interleaved arrangement is helpful to leverage program while erase operation if a contiguous address of memory blocks are going to update by applying erase and then program operations consequently. Such as that, individual in-progress status for program and erase operations can be performed respectively in the flash memory.

Further, in FIG. 2C, corresponding to the implementation of FIG. 2A, each of the memory blocks 2101 to 2108 included in the memory bank BK1 can be arranged into a plurality of sub blocks 2101-L to 2108-L and 2101-R to 2108-R; each of the memory blocks 2109 to 2116 included in the memory bank BK2 can be arranged into a plurality of sub blocks 2109-L to 2116-L and 2109-R to 2116-R. In terms of a physical layout of integrated circuit, with the memory bank BK1 taken as an example, the sub-blocks 2101-L to 2108-L can be disposed on a first side of the corresponding multiplex circuit, and the sub-blocks 2101-R to 2108-R can be disposed on a second side of the corresponding multiplex circuit. The first side is opposite to the second side.

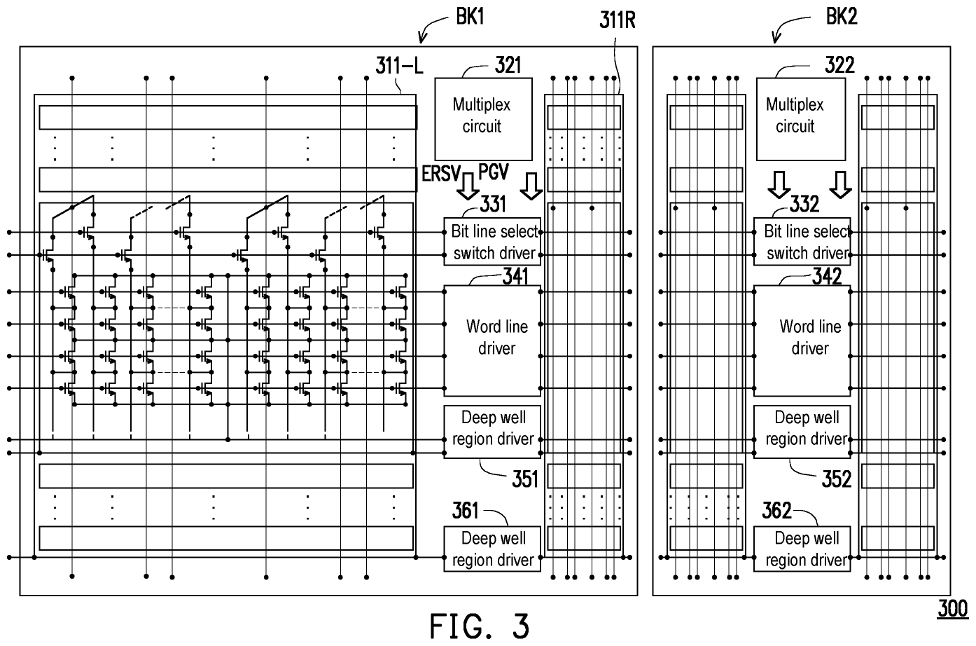

Referring to FIG. 3, FIG. 3 is a schematic diagram illustrating a flash memory in another embodiment of the invention. A flash memory 300 is an NOR flash memory. A plurality of memory blocks can be arranged into the memory bank BK1 and the memory bank BK2. The flash memory 300 includes multiplex circuits 321 and 322 respectively corresponding to the memory banks BK1 and BK2. The memory bank BK1 further includes a bit line select switch driver 331, a word line driver 341 and drivers 351 and 361 for the P-type well inside deep N-type well (PWI) and the deep N-type well (NWD), respectively. The memory bank BK2 further includes a bit line select switch driver 332, a word line driver 342 and drivers 352 and 362 for the P-type well inside deep N-type well (PWI) and the deep N-type well (NWD), respectively.

In addition, the multiplex circuit 321 is configured to provide the erase voltages ERSV or the program voltages PGV to the bit line select switch driver 331, the word line driver 341 and the drivers 351 and 361 to make the memory blocks in the memory bank BK1 execute the erase operation or the program operation. The multiplex circuit 322 is configured to provide the erase voltages ERSV or the program voltages PGV to the bit line select switch driver 332, the word line driver 342 and the drivers 352 and 362 to make the memory blocks in the memory bank BK1 execute the erase operation or the program operation. Among them, the bit line select switch drivers 331 and 332 are configured to control on or off of a plurality of bit line switches; the word line drivers 341 and 342 respectively provide a plurality of word line voltages to a plurality of word lines; the drivers 351 and 352 are used to provide a plurality of bias voltages to a plurality of PWI regions; the drivers 361 and 362 respectively provide a plurality of bias voltages to a plurality of NWD regions.

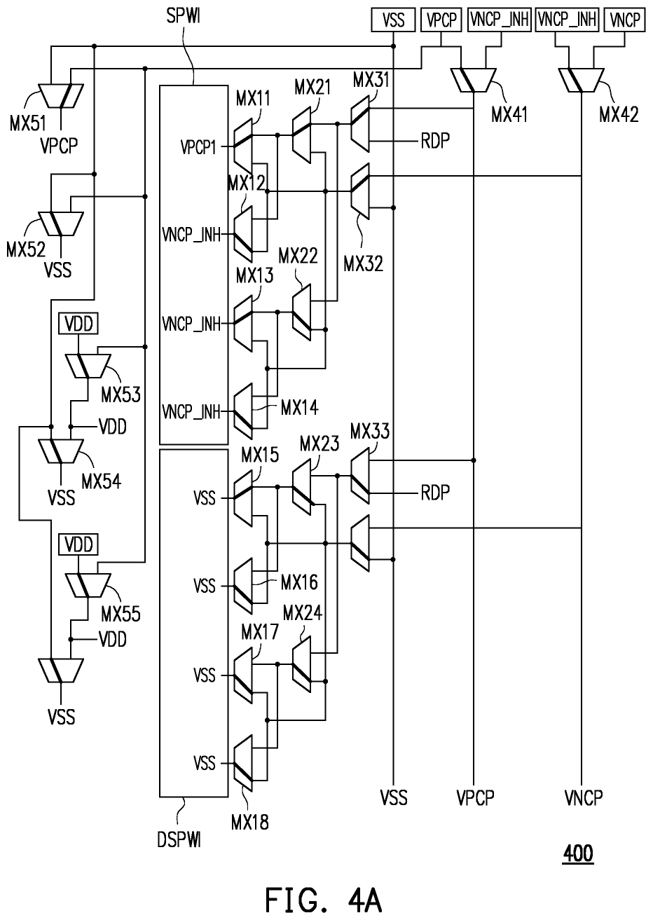

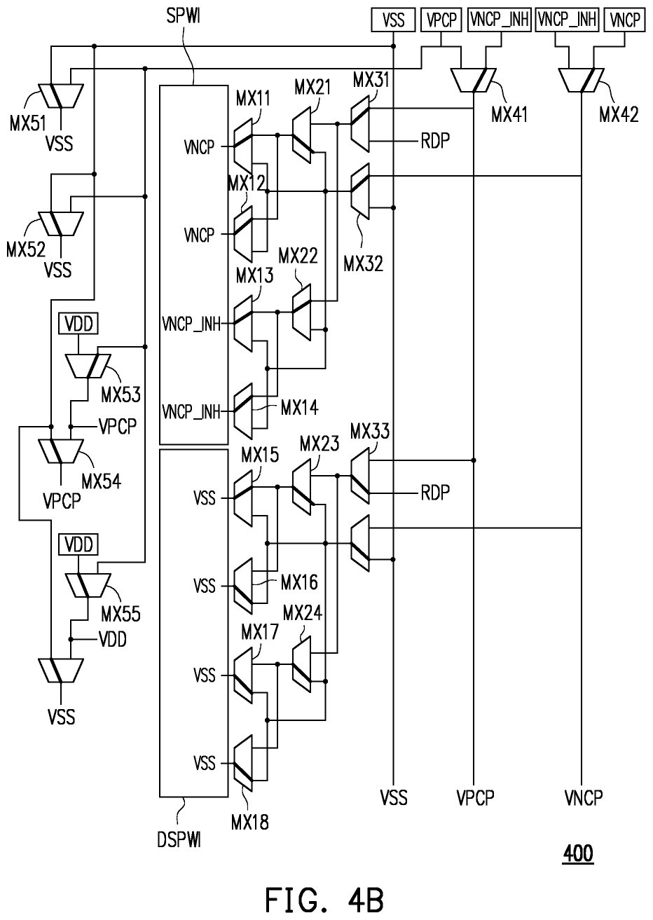

For implementation details of the multiplex circuits 321 and 322, reference can be made according to FIG. 4A and FIG. 4B, which are schematic diagrams illustrating various implementations of a multiplex circuit in the flash memory in the embodiments of the invention. In FIG. 4A and FIG. 4B, a multiplex circuit 400 includes a plurality of voltage selectors MX11 to MX56. The multiplex circuit 400 receives a power voltage VDD, a reference ground voltage VSS, a positive boost voltage VPCP, a negative boost voltage VNCP, a positive mask voltage VPCP_IHN, a negative mask voltage VNCP_INH and a read voltage RDP.

In FIG. 4A, the multiplex circuit 400 executes the program operation. At this time, the multiplex circuit 400 selects the power voltage VDD, the reference ground voltage VSS, the positive boost voltage VPCP, the negative boost voltage VNCP, the positive mask voltage VPCP_INH, the negative mask voltage VNCP_INH and read voltage RDP through the voltage selectors MX11 to MX56, and outputs the power voltage VDD, the positive boost voltage VPCP, the negative mask voltage VNCP_INH and the reference ground voltage VSS as the program voltages.

In detail, the memory blocks corresponding to the multiplex circuit 400 have a plurality of selected PWI regions SPWI and a plurality of un-selected PWI regions DSPWI. In the part corresponding to the selected PWI region SPWI, through a first path formed by the voltage selectors MX41, MX31, MX21 and MX11, the multiplex circuit 400 provides the positive boost voltage VPCP output by the voltage selector MX11 to word lines of selected memory cells in the selected PWI region SPWI. Corresponding to the embodiment of FIG. 3, the positive boost voltage VPCP output by the voltage selector MX11 can be first provided to the word line driver 341 to drive the word lines of the selected memory cells. In addition, the multiplex circuit 400 can provide the negative mask voltage VNCP_INH to word lines of un-selected memory cells in the selected PWI region SPWI respectively through a second path formed by the voltage selectors MX42, MX32 and MX12; through a third path formed by the voltage selectors MX42, MX32, MX22 and MX13; and through a fourth path formed by the voltage selectors MX42, MX32, MX22 and MX14. The four paths mentioned above can be corresponded by decoding a global word line flag GWL and a local word line flag LWL corresponding to the word lines of the memory cells, and a corresponding relationship for receiving the positive boost voltage VPCP or the negative mask voltage VNCP_INH through the corresponding paths is shown in the following table:

| GWL | LWL | Corresponding path |
|---|---|---|
| 1 | 1 | First path |
| 1 | 0 | Second path |
| 0 | 1 | Third path |
| 0 | 0 | Fourth path |

Among them, the memory cells connected by the first path are the selected memory cells, and the memory cells connected by the second path to the fourth path are all the un-selected memory cells.

Further, in the part corresponding to the un-selected PWI region DSPWI, the reference ground voltage VSS is output through a fifth path formed by the voltage selectors MX34 and MX15; a sixth path formed by the voltage selectors MX34 and MX16; a seventh path formed by the voltage selectors MX34 and MX17; and an eighth path formed by the voltage selectors MX34 and MX18. Since the memory cells in the un-selected PWI region DSPWI are all the un-selected memory cells, the reference ground voltage VSS can be provided to the word lines of all the un-selected memory cells in the un-selected PWI region DSPWI through the seventh path and the eighth path described above.

On the other hand, the voltage selector MX51 selects the positive boost voltage VPCP as an output transmitted to the corresponding bit line select switch driver to turn on selected bit line select switches. The voltage selector MX52 selects the reference ground voltage VSS as an output to turn off un-selected bit line select switches. The voltage selector MX53 selects the power voltage VDD as an output to drive the selected NWD regions through the corresponding driver. The voltage selector MX54 selects the reference ground voltage VSS as an output to drive the selected PWI regions through the corresponding driver. The voltage selectors MX55 and MX56 respectively select the power voltage VDD and the reference ground voltage VSS as outputs. The outputs of the voltage selectors MX55 and MX56 are used to drive un-selected NWD regions and un-selected PWI regions, respectively.

Hereinafter, in FIG. 4B, the multiplex circuit 400 is used to perform an erase operation. At this time, the multiplex circuit 400 selects the power voltage VDD, the reference ground voltage VSS, the positive boost voltage VPCP, the negative boost voltage VNCP, the positive mask voltage VPCP_INH, the negative mask voltage VNCP_INH and read voltage RDP through the voltage selectors MX11 to MX56, and outputs the power voltage VDD, the positive boost voltage VPCP, the negative boost voltage VNCP, the positive mask voltage VPCP_INH and the reference ground voltage VSS as the erase voltages.

In detail, the memory blocks corresponding to the multiplex circuit 400 have a plurality of selected PWI regions SPWI and a plurality of un-selected PWI regions DSPWI. In the part corresponding to the selected PWI region SPWI, through a first path formed by the voltage selectors MX42, MX32 and MX11, the multiplex circuit 400 provides the negative boost voltage VNCP output by the voltage selector MX11 to word lines of selected memory cells in the selected PWI region SPWI. The negative boost voltage VNCP output by the voltage selector MX11 can be first provided to the word line driver to drive the word lines of the selected memory cells. Through a second path formed by the voltage selectors MX42, MX32 and MX12, the negative boost voltage VNCP can be provided by an output of the voltage selector MX12 to the word lines of the selected memory cells in the selected PWI region SPWI. In addition, the multiplex circuit 400 can provide the positive mask voltage VPCP_INH to word lines of un-selected memory cells in the selected PWI region SPWI respectively through a third path formed by the voltage selectors MX41, MX31, MX22 and MX13; and a fourth path formed by the voltage selectors MX41, MX31, MX22 and MX14. The four paths mentioned above can be corresponded by decoding a global word line flag GWL and a local word line flag LWL corresponding to the word lines of the memory cells, and a corresponding relationship for receiving the negative boost voltage VNCP or the positive mask voltage VPCP_INH through the corresponding paths is shown in the following table:

| GWL | LWL | Corresponding path |
|---|---|---|
| 1 | 1 | Third path and fourth path |
| 0 | 1 | First path and second path |

Among them, the memory cells connected by the first path and second path are the selected memory cells, and the memory cells connected by the third path and the fourth path are all the un-selected memory cells.

Further, in the part corresponding to the un-selected PWI region DSPWI, the reference ground voltage VSS is output through a fifth path formed by the voltage selectors MX34 and MX15; a sixth path formed by the voltage selectors MX34 and MX16; a seventh path formed by the voltage selectors MX34 and MX17; and an eighth path formed by the voltage selectors MX34 and MX18. Since the memory cells in the un-selected PWI region DSPWI are all the un-selected memory cells, the reference ground voltage VSS can be provided to the word lines of all the un-selected memory cells in the un-selected PWI region DSPWI through the seventh path and the eighth path described above.

On the other hand, the voltage selector MX51 selects the reference ground voltage VSS as an output transmitted to the corresponding bit line select switch driver to turn off the selected bit line select switches. The voltage selector MX52 selects the reference ground voltage VSS as an output to turn off un-selected bit line select switches. The voltage selector MX53 selects the positive boost voltage VPCP as an output to drive selected NWD regions through the corresponding driver. The voltage selector MX54 selects the positive boost voltage VPCP as an output to drive selected PWI through the corresponding driver. The voltage selectors MX55 and MX56 respectively select the power voltage VDD and the reference ground voltage VSS as outputs. The outputs of the voltage selectors MX55 and MX56 are used to drive un-selected NWD regions and un-selected PWI regions, respectively.

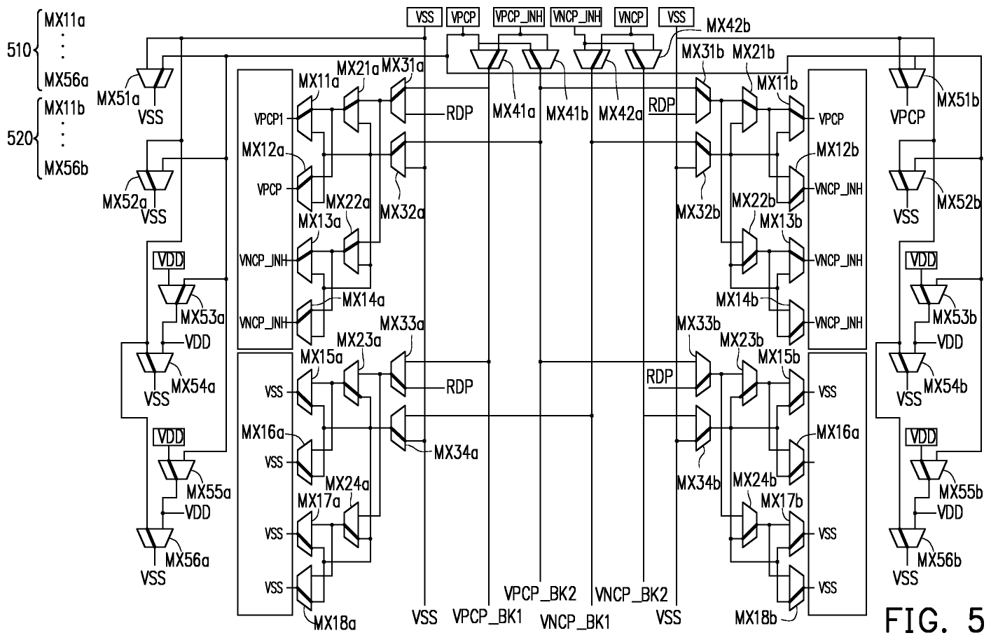

Referring to FIG. 5, FIG. 5 is a schematic diagram of an implementation of multiple multiplex circuits corresponding to different memory banks in a flash memory according to an embodiment of the invention. FIG. 5 includes multiplex circuits 510 and 520. The multiplex circuit 510 includes voltage selectors MX11a to MX56a, and the multiplex circuit includes voltage selectors MX11b to MX56b. In this embodiment, the multiplex circuit 510 can perform the program operation as shown in FIG. 4A, and the multiplex circuit 520 can simultaneously perform the erase operation as shown in FIG. 4B. In this way, while the erase operation is executed by one memory bank (through the erase voltages provided by the multiplex circuit 520), it is possible to smoothly complete the program operation executed by another memory bank (through the program voltages provided by the multiplex circuit 510). As a result, the time required for data writing in flash memory can be effectively reduced.

Incidentally, in this embodiment, a positive boost voltage VPCP_BK1 output by the voltage selector MX41a is provided to the memory bank corresponding to the multiplex circuit 510; a positive boost voltage VPCP_BK2 output by the voltage selector MX41b is provided to the memory bank corresponding to the multiplex circuit 520; a negative boost voltage VNCP_BK1 output by the voltage selector MX42a is provided to the memory bank corresponding to the multiplex circuit 510; a negative boost voltage VNCP_BK2 output by the voltage selector MX42b is provided to the memory bank corresponding to the multiplex circuit 520.

In addition, in the embodiments of FIG. 4A to FIG. 5, the so-called positive boost voltage VPCP is a voltage greater than 0V generated by a boost mechanism (e.g., a charge pump) based on a reference voltage. The negative boost voltage VNCP is a voltage less than 0V generated by a negative boost mechanism (e.g., the charge pump) based on the reference voltage. The positive mask voltage VPCP_INH and the negative mask voltage VNCP_INH are designed based on voltage values suitable for masking the un-selected memory cells in the flash memory. In the invention, those voltages can be set and implemented in a manner well known to those with ordinary knowledge in the art without particular limitations.

In addition, control signals received by the voltage selectors MX11a to MX56a and MX11b to MX56b can be generated by a controller set corresponding to the flash memory. Regarding the implementation details of the voltage selectors MX11a to MX56a and MX11b to MX56b, any voltage selection circuit well known to those skilled in the art can be used for implementation without particular limitations.

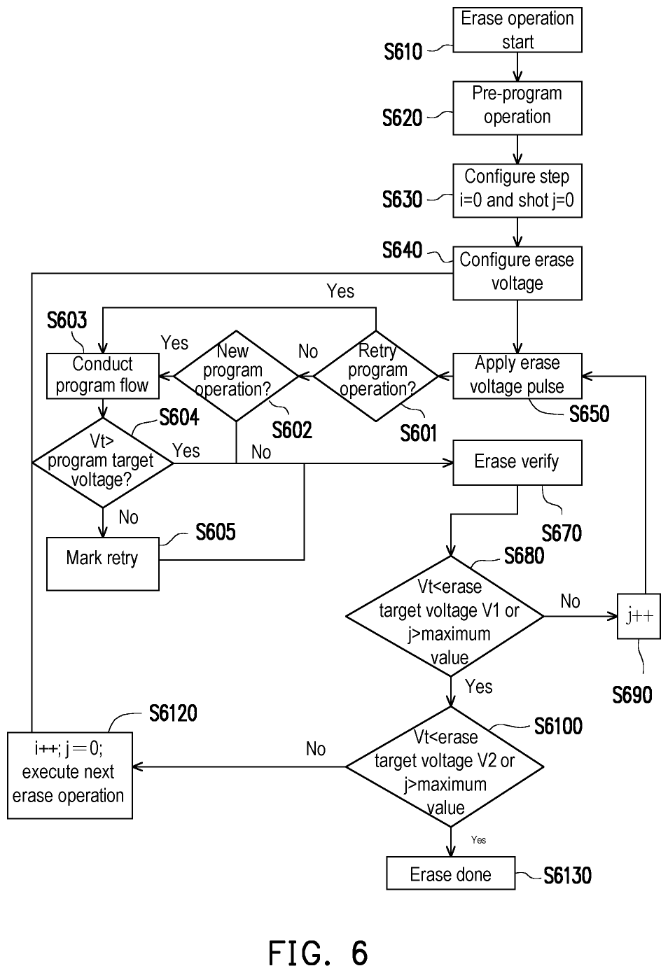

Referring to FIG. 6, FIG. 6 illustrates a flowchart of operations of a programming while erasing operation executed by the flash memory in an embodiment of the invention. In FIG. 6, steps S610 to S6130 are used to perform the erase operation, and steps S601 to S605 are used to perform the program operation. Among them, the erase operation and the program operation are respectively applied to different memory banks.

Specifically, in step S610, the erase operation for a first memory bank is started. In step S620, a pre-program operation is executed. Then, a step i=0 and a shot j=0 are configured in step S630. Here, it should be noted that the erase operation in this embodiment is executed by a multi-step and multi-shot method. Here, the so-called “shot” refers to an erase voltage pulse applied to the memory cell on which the erase operation is executed. The so-called “multi-stage and multi-shot method” is to configure one target voltage for each erase step, and apply one or more erase voltage pulses (shots) in each erase step so that a threshold voltage of the erased memory cell can be less than the configured target voltage. After multiple erase steps are executed, the threshold voltage of the memory cell can eventually become smaller than an erase target voltage configured.

Next, in step S640, a voltage value of an erase voltage is configured. Then, in step S650, the erase voltage pulse is applied to the memory cell according to the voltage value configured in step S640. Here, it should be noted that the erase voltage pulse can last for one time interval. With this time interval, the program operation of steps S601 to S605 may be executed for a second memory bank.

First, in step S601, whether to retry stating the program operation again can be determined according to whether the program operation has been executed previously. If the determination result is Yes, the step S603 can be directly performed to conduct a program flow. On the contrary, if the determination result is No, whether it is required to execute a new program operation is determined in step S602. Here, if the determination result of step S602 is Yes, step S603 is performed; otherwise, if the determination result of step S602 is No, step S670 is performed.

Here, it should be noted that, in step S603, a program voltage pulse can be applied to a programmed memory cell one or many times. Then, whether a threshold voltage Vt of the programmed memory cell is greater than a program target voltage is determined in step S604. If the threshold voltage Vt of the memory cell is greater than the program target voltage, it indicates that the program operation is done, and step S670 can be performed. Otherwise, if the threshold voltage Vt of the memory cell is not greater than the program target voltage in the time interval, it indicates that the program operation is undone, and a mark retry operation can be performed by using a flag in step S605.

Here, it should be noted that, in step S650, the time interval for applying the erase voltage pulse is limited. Therefore, if the time interval for applying the erase voltage pulse is not long enough to complete the program operation of the memory cell, the undone program operation of the memory cell can be completed in another time interval for applying the next erase voltage pulse by the mark retry operation of step S605.

What's more worth mentioning is that when the erase voltage pulse is stably supplied, the power consumed by the flash memory for the erase operation is relatively low. Therefore, the program operation simultaneously executed by another memory bank at this time will not cause the problem of excessive power consumption.

From the above description, it can be known that, in the embodiments of the invention, the program operation in the programming while erasing operation is executed by being embedded in the erase operation, and no additional time interval is required. Therefore, the program operation does not have to be completed very quickly, but can be executed through the degraded program operation to reduce the program current required in the program operation so that the program current can be less than the expected value to effectively reduce power consumption.

Step S670 is performed after step S650 is done, and is used to execute an erase verification. In step S680, whether the threshold voltage Vt of the erased memory cell is less than a target voltage V1 at this step is determined, or whether j is greater than a preset maximum value is determined. Step S6100 is performed if one of the two determination results above is Yes; and step S690 is performed if the two determination results are both No.

In step S690, j is incremented by 1 (j++), and then step S650 is performed to apply the next erase voltage pulse.

In step S6100, whether the threshold voltage Vt of the erased memory cell is less than the erase target voltage is determined, or whether j is greater than the maximum value is determined. The erase operation is done (step S6130) if one of the two determination results above is Yes. If the two determination results are both No, step S6120 is performed to: increment i by 1 (i++); return j to zero; and execute the next step of the erase operation.

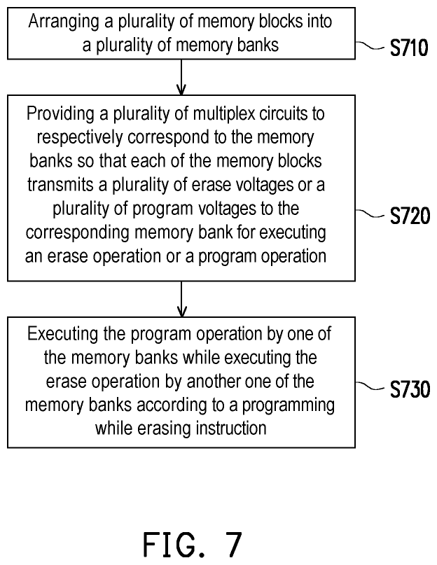

Referring to FIG. 7, FIG. 7 is a flowchart illustrating a writing method of a flash memory in an embodiment of the invention. Here, in step S710, a plurality of memory blocks are arranged into a plurality of memory banks. Then, in step S720, a plurality of multiplex circuits are provided to respectively correspond to the memory banks so that each of the memory blocks transmits a plurality of erase voltages or a plurality of program voltages to the corresponding memory bank for executing an erase operation or a program operation. Next, in step S730, the program operation is executed by one of the memory banks while the erase operation is executed by another one of the memory banks according to a programming while erasing instruction.

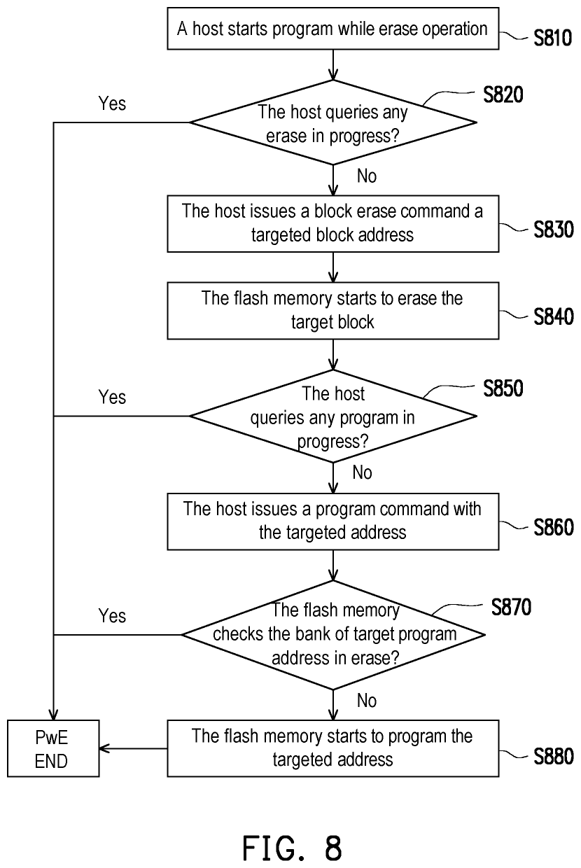

Please refer to FIG. 8, which is a flow chart of illustrating a writing method of a flash memory in another embodiment of the invention. In a step S810, a host starts a program while erase operation (PwE). The host can be an electronic device external from the flash memory. In a step S820, the host queries any erase in progress in the flash memory. If a query result of the step S820 is yes, the PwE operation is end, and if the query result of the step S820 is no, a step S830 can be performed.

In the step S830, the host issues a block erase command with a targeted memory block address, and the flash memory starts to erase the target address in a step S840. Then, in a step S850, the host queries any program in progress in the flash memory. If a query result of the step S850 is yes, the another program operation is not allowed because there is already a program operation in place, and if the query result of the step S850 is no, a step S860 can be performed. The host issues a program command with the target address in a step S860, and the flash memory checks whether the program address is in erase or not in a step S870.

If a check result in the step S870 is yes, the PwE operation may be end, and if the check result in the step S870 is no, the flash memory starts to program the targeted address in a step S880.

In another implementation, the host can just start from S850 to performance PwE if it knows an erase operation already in place.

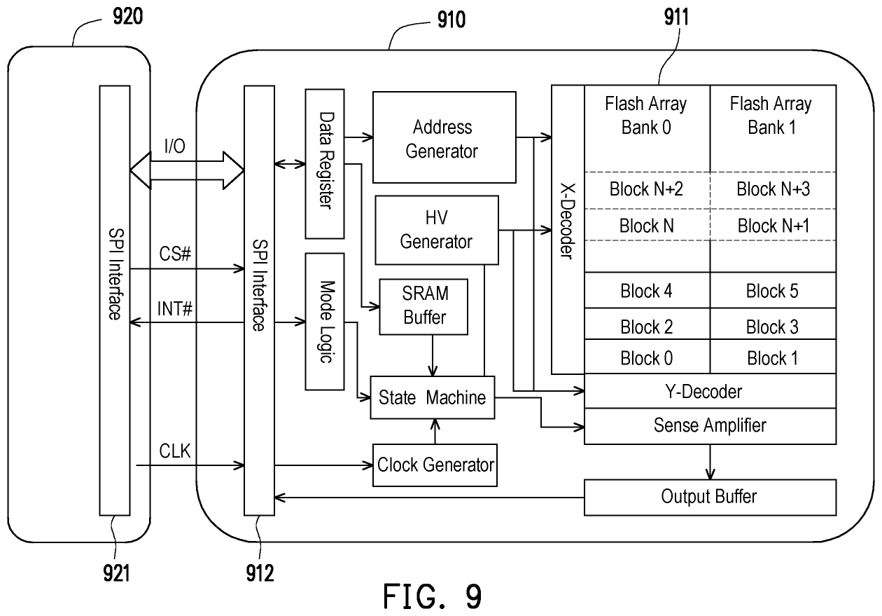

Please refer to FIG. 9, which illustrates a block diagram of a flash memory with a host chip according to an embodiment of present disclosure. The flash memory 910 has a hardware structure same to the flash memory chip 102 in FIG. 1B. The host chip 920 is coupled to the flash memory 910. The flash memory 910 has a memory array 911 including a flash array bank 0 and a flash array bank 1. Each of the flash array bank 0 and the flash array bank 1 has a plurality of blocks (block 0 to block N+2). The host chip 920 may has a SPI interface 921 coupled to a SPI interface 912 of the flash memory 910 to transport one or more commands. The host chip 920 and the flash memory 910 can perform the steps in FIG. 8. In here, the flash memory 910 may be flash memory chip.

In summary, the invention provides the programming while erasing instruction for executing the program operation by one of the memory banks while executing the erase operation by another one of the memory banks. Under the condition of a large amount of data update, by inserting the program operation that can be completed relatively quick into the erase operation with a relatively slow speed, the time required for the write operation of the flash memory is effectively reduced. Furthermore, according to the embodiments of the invention, the programming while erasing operation can reduce required power consumption by providing the degraded program operation to further improve a working performance of the flash memory.

What is claimed is:

1. A flash memory, comprising:
a plurality of memory blocks, arranged into a plurality of memory banks; and
a plurality of multiplex circuits, respectively coupled to the memory banks, each of the multiplex circuits being configured to transmit a plurality of erase voltages or a plurality of program voltages to the corresponding memory bank for executing an erase operation or a program operation,
wherein the program operation is executed by one of the memory banks while the erase operation is executed by another one of the memory banks according to a programming and a erasing instructions.

2. The flash memory of claim 1, wherein the memory blocks comprise a plurality of first memory blocks corresponding to a first memory bank and a plurality of second memory blocks corresponding to a second memory bank.

3. The flash memory of claim 2, wherein physical addresses of the first memory blocks and the second memory blocks are interleaved with each other.

4. The flash memory of claim 2, wherein the first memory blocks have continuous physical addresses, and the second memory blocks have continuous physical addresses.

5. The flash memory of claim 1, wherein while the first memory bank is executing the erase operation, a first multiplex circuit corresponding to the first memory bank provides an erase voltage pulse to the first memory bank within a time interval, and a second multiplex circuit corresponding to the second memory bank makes the second memory bank execute the program operation within the time interval.

6. The flash memory of claim 1, further comprising:
individual in-progress status for program and erase operations, respectively.

7. The Flash memory of claim 6, wherein a plurality of status flags, respectively corresponding to the memory banks, each of the status flags recording an erase in-progress status or a program in-progress status of the corresponding memory bank.

8. The flash memory of claim 1, wherein the program operation is a degraded program operation according to the programming while erasing instruction, and a program current corresponding to the program operation is less than an expected value.

9. A writing method of flash memory, comprising:
arranging a plurality of memory blocks into a plurality of memory banks;
providing a plurality of multiplex circuits to respectively correspond to the memory banks so that each of the multiplex circuits transmits a plurality of erase voltages or a plurality of program voltages to the corresponding memory bank for executing an erase operation or a program operation; and
executing the program operation by one of the memory banks while executing the erase operation by another one of the memory banks according to a programming while erasing instruction.

10. The writing method of flash memory of claim 9, wherein the step of executing the program operation by one of the memory banks while executing the erase operation by another one of the memory banks according to the programming while erasing instruction comprises:
providing an erase voltage pulse to a first memory bank within a time interval for executing the erase operation; and
executing the program operation by a second memory bank within the time interval.

11. The writing method of flash memory of claim 9, wherein the erase voltages comprise a power voltage, a reference ground voltage, a negative boost voltage, a positive boost voltage and a positive mask voltage, and the program voltages comprise the power voltage, the reference ground voltage, the positive boost voltage and a negative mask voltage.

12. The writing method of flash memory of claim 9, further comprising:
executing the program operation based on a degraded program operation according to the programming while erasing instruction, a program current corresponding to the program operation being less than an expected value.

13. The writing method of flash memory of claim 9, wherein the step of arranging the memory blocks into the memory banks comprises:
arranging the memory blocks into the memory banks according to an arrangement sequence of physical addresses of the memory blocks.
